(19) United States
(12) Patent Application Publication
(10) Pub. No.: US 2026/0182200 A1
(43) Pub. Date: Jun. 25, 2026

(54) DISPLAY DEVICE

(71) Applicant: LG Display Co., Ltd., Seoul (KR)

(72) Inventors: Hyun-Jik BAE, Paju-si (KR); Min-Ho LEE, Paju-si (KR)

(21) Appl. No.: 19/403,241

(22) Filed: Nov. 28, 2025

(30) Foreign Application Priority Data
Dec. 23, 2024 (KR) 10-2024-0194022

(51) Int. Cl. H10K 59/65; H10K 59/121; H10K 59/131; H10K 59/35; H10K 59/40; H10K 59/80

(52) U.S. Cl. CPC H10K 59/65; H10K 59/1213; H10K 59/131; H10K 59/353; H10K 59/40; H10K 59/879; H10K 59/8792

(57) ABSTRACT

A display device including a display panel that includes a display area having a sensing area, the sensing area including a first sensor display area, a second sensor display area, and a sensor transparent area, a sensor module disposed under the display panel and corresponding to the sensing area, and a plurality of sensor subpixels disposed in the first and second sensor display areas, in which the sensor transparent area is defined by a plurality of gate lines and a plurality of data lines, and the second sensor display area overlaps the plurality of gate lines.

### CROSS REFERENCE TO RELATED APPLICATION

This application claims priority from and the benefit of Korean Patent Application No. 10-2024-0194022, filed on Dec. 23, 2024, which is hereby incorporated by reference for all purposes as if fully set forth herein.

### BACKGROUND

### Field

Embodiments of the invention relate generally to a display device, and more particularly, to a display device including a camera with an improved lifetime.

### Discussion of the Background

As information technology is progressed, various display devices having a small size and a thin profile such as a liquid crystal display (LCD), an organic light emitting diode (OLED) display, a plasma display panel (PDP), and a micro light emitting diode display device have been suggested.

These display devices often include a camera to provide various functions for a user. A camera hole is typically formed in the display device for the camera. Since a region corresponding to the camera hole does not emit a light, the region corresponding to the camera hole is recognized by a user and an image is often deteriorated by the region corresponding to the camera hole.

The above information disclosed in this Background section is only for understanding of the background of the inventive concepts, and, therefore, it may contain information that does not constitute prior art.

### SUMMARY

A display device according to embodiments of the invention substantially obviates one or more of the problems due to limitations and disadvantages of the related art.

A display device according to embodiments of the invention is capable of improving an image in a region corresponding to a sensor.

A display device according to embodiments is also capable of preventing shortening of a lifetime due to an over-current by maximizing an emission area of a region corresponding to a sensor.

Additional features of the inventive concepts will be set forth in the description which follows, and in part will be apparent from the description, or may be learned by practice of the inventive concepts. These and other advantages of the disclosure will be realized and attained by the structure particularly pointed out in the written description and claims hereof as well as the appended drawings.

A display device according to an embodiment includes a display panel including a display area having a sensing area, the sensing area including a first sensor display area, a second sensor display area, and a sensor transparent area; a sensor module disposed under the display panel and corresponding to the sensing area; and a plurality of sensor subpixels disposed in the first and second sensor display areas, in which the sensor transparent area is defined by a plurality of gate lines and a plurality of data lines, and the second sensor display area overlaps the plurality of gate lines.

The plurality of gate lines may include first, second, and third gate lines disposed at an upper portion of the first sensor display area and the sensor transparent area, and the plurality of sensor subpixels may include first, second, and third sensor subpixels connected to the first, second, and third gate lines, respectively.

The first, second, and third sensor subpixels may correspond to red, green, and blue colors, respectively.

The first and second sensor subpixels may be disposed in the first sensor display area, and the third sensor subpixel may be disposed in the second sensor display area.

The third sensor subpixel may overlap the plurality of gate lines.

The third sensor subpixel may extend from a portion corresponding to the first sensor display area to a portion corresponding to the sensor transparent area.

The second sensor subpixel may be formed in plural and at least one of the second sensor subpixels may be disposed in the first sensor display area, the first sensor subpixel may be disposed in the second sensor display area overlapping the plurality of gate lines at an upper portion of the first sensor display area, and the third sensor subpixel may be disposed in the second sensor display area overlapping the plurality of gate lines at a lower portion of the first sensor display area.

Each of the first and third sensor subpixels may overlap the plurality of gate lines.

The second sensor subpixel may be formed in plural and at least one of the second sensor subpixels may be disposed in the first sensor display area, the first sensor subpixel may be disposed in the second sensor display area overlapping the plurality of gate lines at an upper portion of the first sensor display area, the third sensor subpixel may be disposed in the second sensor display area overlapping the plurality of gate lines at a lower portion of the first sensor display area, and a width of at least one of the first sensor subpixel and the third sensor subpixel may be greater than that of the second sensor subpixel.

Each of the plurality of sensor subpixels may include a substrate, a thin film transistor disposed on the substrate, and a light emitting diode disposed on the thin film transistor.

Each of the plurality of sensor subpixels may further include a black matrix configured to block light emitted from an adjacent one of the plurality of sensor subpixels, and a lens corresponding to an opening of the black matrix.

The plurality of sensor subpixels in the first sensor display area may be structured the same as the plurality of sensor subpixels in the second sensor display area.

Each of the plurality of sensor subpixels may further include a touch sensing unit disposed between the black matrix and the lens.

A display device according to another embodiment includes a substrate including a plurality of pixels defined by a plurality of gate lines and a plurality of data lines, and a plurality of subpixels in each of the plurality of pixels, in which at least one of the plurality of subpixels overlaps at least one of the plurality of gate lines.

Each of the plurality of subpixels may include a thin film transistor disposed on the substrate, a light emitting diode disposed on the thin film transistor, a black matrix configured to block a light emitted from an adjacent one of the plurality of subpixels, and a lens corresponding to an opening of the black matrix.

The substrate may include a sensor area configured to display an image and transmit light to a sensor module.

A display device according to still another embodiment includes a display panel including a plurality of signal lines, the display panel having an active area and a sensing area, a sensor module disposed on the display panel and corresponding to the sensing area, in which the active area includes a plurality of pixels, each pixel including a plurality of subpixels, the sensing area includes a first sensor display area, a second sensor display area, and a sensor transparent area, each of the first and second sensor display areas including a sensor subpixel, and an area of at least one of the sensor subpixels is greater than an area of at least one of the subpixels in the active area.

The sensor subpixel of the second sensor display area may overlap at least one of the signal lines.

A width of the sensor subpixel in the second sensor display area may be greater than a width of at least one of the subpixels in the active area.

A width of the sensor subpixel in the second sensor display area may be greater than a width of the sensor subpixel in the first sensor display area, and the sensor subpixels in the first and second sensor display areas may be configured to emit light of different colors.

The sensor subpixel in the first sensor display area may be formed in plural, and the number of the sensor subpixels in the first sensor display area may be greater than the number of the sensor subpixel in the second sensor display area.

The second sensor display area may be formed in plural, and widths of the sensor subpixels in the second sensor display areas may be different from each other.

The second sensor display area may be formed in plural, and the sensor subpixels in adjacent second sensor display areas may be configured to emit light of different colors.

At least one of the sensor subpixels may include a lens, the plurality of signal lines may include a plurality of gate lines and a plurality of data lines, and at least a portion of the sensor subpixel in the second sensor display area may overlap at least one of the sensor subpixels in the first sensor display area along a line parallel to one of the data lines.

The sensor transparent area may be formed in plural, and the sensor subpixel in the second sensor display area may span over two adjacent sensor transparent areas in a plan view.

The sensor transparent area may be configured to transmit an external light to the sensor module, and the number of the sensor transparent area may be greater than the number of the first and second sensor display areas.

The number of the subpixels in one pixel may be greater than the number of the sensor subpixels in the first sensor display area, an area of the one pixel may be substantially the same as an area of the first sensor display area, and each sensor subpixel in the first sensor display area may be configured to emit light having a greater luminance than that emitted from each subpixel.

The sensor subpixel in the second sensor display area may overlap two signal lines that intersect each other, and the sensor subpixel in the first sensor display area may not overlap the signal lines.

The sensor module may include at least one of a camera, an illuminance sensor, and a fingerprint sensor.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic block diagram of a display device according to an embodiment of the invention.

FIG. 2 is a schematic view of a subpixel of a display device according to an embodiment of the invention.

FIG. 3 is a circuit diagram of a subpixel of a display device according to an embodiment of the invention.

FIG. 4 is an exploded perspective view of a display device according to an embodiment of the invention.

FIG. 5 is a plan view of a display panel of a display device according to an embodiment of the invention.

FIG. 6 is a magnified view of portion A of FIG. 5 according to a first embodiment of the invention.

FIG. 7 is a plan view illustrating a display area and a sensor area of a display device according to a second embodiment of the invention.

FIG. 8 is a cross-sectional view taken along line I-I′ of FIG. 7, illustrating a sensor subpixel of the display device according to the second embodiment of the invention.

FIG. 9A is a view schematically illustrating a sensing area of a display device according to a third embodiment of the invention.

FIG. 9B is a view schematically illustrating a sensing area of a display device according to a fourth embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

The term “display device” as used herein may include a display device in a narrow sense, such as liquid crystal module (LCM), an organic light emitting diode (OLED) module, and a quantum dot (QD) module including a display panel and a driving unit for driving the display panel. In addition, the term “display device” may include a complete product (or a final product) including the LCM, the OLED module, and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device according to embodiment of the invention may include an applied product or a set device of a final user's device including the LCM, the OLED module, and the QD module, as well as a display device in a narrow sense such as the LCM, the OLED module, and the QD module.

In some embodiments, the LCM, the OLED module, and the QD module having a display panel and a driving unit may be expressed as “a display device”, and an electronic apparatus of a complete product including the LCM, the OLED module, and the QD module may be expressed as “a set device.” For example, a display device in a narrow sense may include a display panel of a liquid crystal, an organic light emitting diode, and a quantum dot, and a source printed circuit board (PCB) of a control unit for driving the display panel, and a set device may further include a set PCB of a set control unit electrically connected to the source PCB for controlling the entire set device.

The display panel according to embodiments may include all types of display panels such as a liquid crystal display panel, an organic light emitting diode display panel, a quantum dot display panel, and an electroluminescent display panel. As such, the display panel according to embodiments is not limited to a specific display panel of a bezel bending having a flexible substrate for an organic light emitting diode display panel and a lower back plate supporter. A shape or a size of the display panel for the display device is not limited thereto.

For example, when the display panel is an organic light emitting diode display panel, the display panel may include a plurality of gate lines, a plurality of data lines, and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of a moisture or an oxygen into the emitting element layer. In addition, a layer on the array may include an inorganic light emitting layer, for example, a nano-sized material layer or a quantum dot.

The thin film transistor according to embodiments may include one of an oxide thin film transistor, an amorphous silicon thin film transistor, a low temperature polycrystalline silicon thin film transistor.

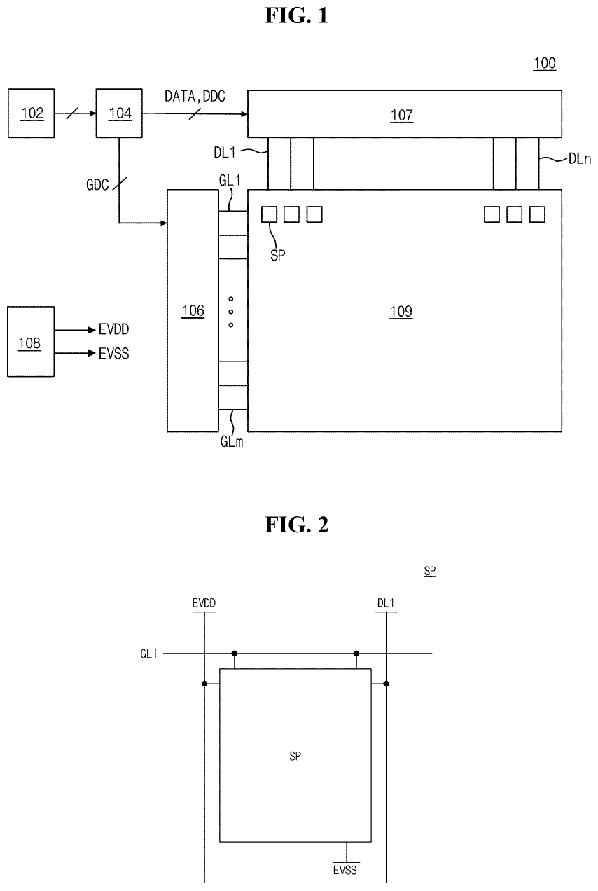

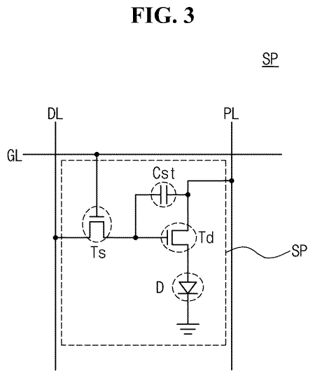

FIG. 1 is a schematic block diagram of a display device according to an embodiment of the invention, and FIG. 2 is a schematic view of a subpixel of a display device according to an embodiment of the invention.

Referring to FIG. 1, a display device 100 according to an embodiment may include an image processing unit 102, a timing controlling unit 104, a gate driving unit 106, a data driving unit 107, a power supplying unit 108, and a display panel 109.

The image processing unit 102 may output a plurality of timing signals for various units, as well as an image signal supplied from an exterior. For example, the plurality of timing signals may include a data enable signal, a vertical synchronization signal, a horizontal synchronization signal, and a clock signal.

The timing controlling unit 104 may receive the image signal and the plurality of timing signals from the image processing unit 102. The timing controlling unit 104 may generate an image data DATA, a gate control signal GDC, and a data control signal DDC using the image signal and the plurality of timing signals. The timing controlling unit 104 may transmit the gate control signal GDC to the gate driving unit 106, and transmit the image data DATA and the data control signal DDC to the data driving unit 107.

The gate driving unit 106 may generate a gate signal (e.g., a gate voltage, a scan signal) using the gate control signal GDC transmitted from the timing controlling unit 104, and apply the gate signal to a plurality of gate lines GL1 to GLm of the display panel 109. The gate driving unit 106 may be formed as an integrated circuit (IC), without being limited thereto.

The gate driving unit 106 may be implemented as a gate-in-panel (GIP) type where the gate driving unit 106 is disposed on a substrate of the display panel 109. However, the inventive concepts are not limited thereto, and in some embodiments, the gate driving unit 106 may be implemented as a chip-on-glass (COG) type, a chip-on-film (COF) type, and tape-carrier-package (TCP) type.

The data driving unit 107 may generate a data signal (e.g., a data voltage) using the data control signal DDC and the image data DATA transmitted from the timing controlling unit 104, and apply the data signal to a plurality of data lines DL1 to DLn of the display panel 109. The data driving unit 107 may sample and latch the image data DATA of a digital type to output the data signal of an analog type based on a gamma reference voltage. The data driving unit 107 may be formed as an integrated circuit (IC), without being limited thereto.

The power supplying unit 108 may output a high level voltage Vdd and a low level voltage Vss. The power supplying unit 108 may supply the high level voltage Vdd to the display panel 109 through a first power line EVDD and supplies the low level voltage Vss to the display panel 109 through a second power line EVSS. In addition, the high level voltage Vdd and the low level voltage Vss of the power supplying unit 108 may be supplied to the gate driving unit 106 or the data driving unit 107 for driving.

The display panel 109 may display an image using the gate signal of the gate driving unit 106, the data signal of the data driving unit 107, and the high level voltage Vdd and the low level voltage Vss of the power supplying unit 108.

The display panel 109 may include a plurality of subpixels SP, the plurality of gate lines GL1 to GLm, and the plurality of data lines DL1 to DLn. The plurality of subpixels SP may include red, green, and blue subpixels SP or white, red, green, and blue subpixels SP. The white, red, green, and blue subpixels SP may have the same area as each other or may have a different area from each other.

Referring to FIG. 2, a subpixel SP may be connected to the gate line GL1, the data line DL1, the first power line EVDD, and the second power line EVSS. A driving method, a number of a transistor, and a capacitor of the subpixel SP may be determined according to a structure of a subpixel circuit. For example, the subpixel SP may have a structure of 2T1C including two transistors and one capacitor. In another embodiment, the subpixel SP may have a structure of n transistors and m capacitors, such as 3T1C, 4T1C, 5T1C, 6T1C, 7T1C, 3T2C, 4T2C, 5T2C, 6T2C, 7T2C, and 8T2C, where n and m are natural numbers.

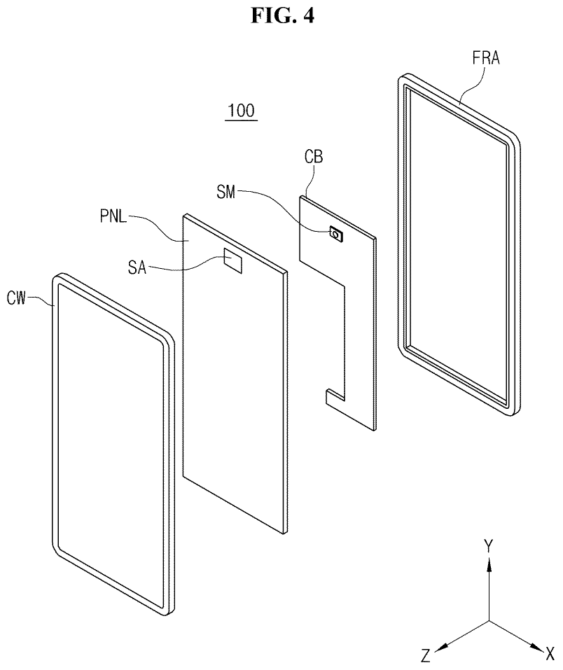

FIG. 3 is a circuit diagram of a subpixel of a display device according to an embodiment of the invention.

Referring to FIG. 3, the display device 100 may include the gate line GL, the data line DL, and the power line PL crossing each other to define the subpixel SP. A switching transistor Ts, a driving transistor Td, a storage capacitor Cst, and a light emitting diode D may be disposed in the subpixel SP.

The switching transistor Ts may be connected to the gate line GL and the data line DL. The driving transistor Td and the storage capacitor Cst may be connected between the switching transistor Ts and the power line PL. The light emitting diode D may be connected to the driving transistor Td.

When the switching transistor Ts is turned on according to the gate signal of the gate line GL, the data signal of the data line DL may be applied to a gate electrode of the driving transistor Td and one capacitor electrode of the storage capacitor Cst through the switching transistor Ts.

Since the driving transistor Td may be turned on according to the data signal, a current proportional to the data signal may flow from the power line PL to the light emitting diode D through the driving transistor Td, and the light emitting diode D may emit light of a luminance proportional to the current flowing through the driving transistor Td.

The storage capacitor Cst may be charged up with a voltage proportional to the data signal to maintain a voltage of the gate electrode of the driving transistor Td constant for one frame.

In FIG. 3, although the subpixel SP is exemplarily illustrated as including two transistors Ts and Td and one capacitor Cst, the inventive concepts are not limited thereto. In some embodiments, the subpixel SP may include three or more transistors and two or more capacitors.

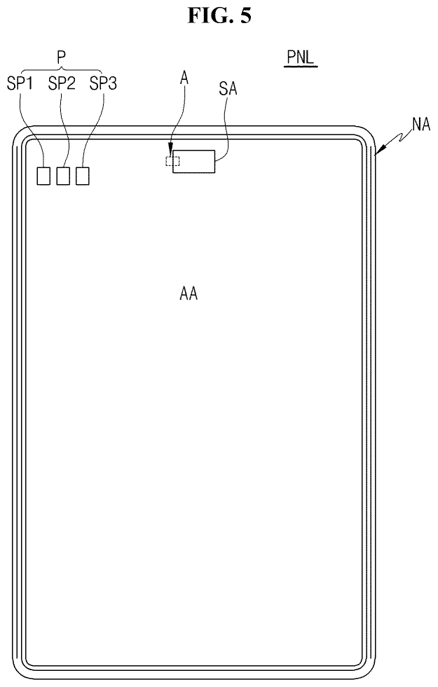

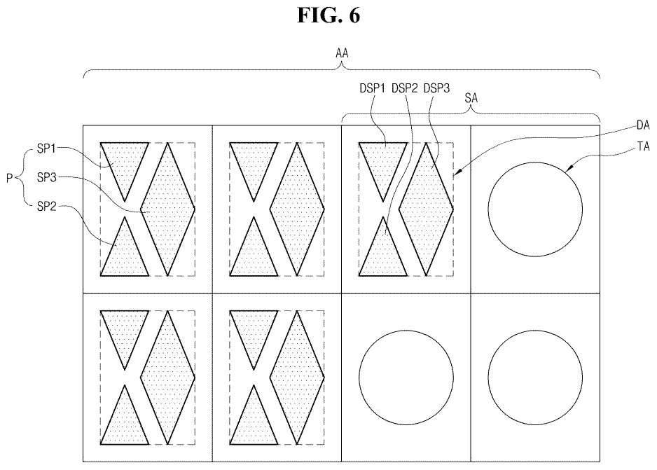

FIG. 4 is an exploded perspective view of a display device according to an embodiment of the invention, and FIG. 5 is a plan view of a display panel of a display device according to an embodiment of the invention.

Referring to FIGS. 4 and 5, the display device 100 according to an embodiment of the invention may include the display panel PNL, a sensor module SM, a circuit board CB, a cover window CW, and a frame FRA.

The display panel PNL may include a display area AA where an image is displayed and a non-display area NA surrounding the display area AA.

A pixel P including a plurality of subpixels SP1, SP2, and SP3 may be disposed in the display area AA. For example, the pixel P may include red, green, and blue subpixels or white, red, green, and blue subpixels, without being limited thereto.

Although not shown, the plurality of gate lines and the plurality of data lines may be disposed in the display area AA, and each subpixel SP1, SP2, and SP3 may be disposed in a crossing region of the gate line and the data line. Each subpixel SP1, SP2, and SP3 may include a switching element such as a transistor and a display element for displaying an image.

For example, the display element may include an organic light emitting diode display element, a liquid crystal display element, a quantum dot display element, a micro light emitting diode (LED) display element, and a mini light emitting diode (LED) display element.

The gate driving unit and the data driving unit supplying various signals to each subpixel SP1, SP2, and SP3 may be disposed in the non-display area NA. The gate driving unit may supply the gate signal to each subpixel SP1, SP2, and SP3 through the gate line, and the data driving unit may supply the data signal to each subpixel SP1, SP2, and SP3 through the data line. The gate driving unit may have a gate-in-panel (GIP) type where the gate driving unit 106 is disposed on a substrate of the display panel PNL, without being limited thereto.

The sensor module SM may be disposed under a rear surface of the display panel PNL. The sensor module SM may overlap the display area AA of the display panel PNL. The sensor module SM may include various kinds of elements that utilize an external input through the display panel PNL. For example, the sensor module SM may include a camera, an illuminance sensor, and a fingerprint sensor, without being limited thereto.

The display device 100 according to an embodiment of the invention may have a configuration in which the sensor module SM is disposed beneath the display panel PNL, thus providing an under display camera (UDC) type or an under display infrared (UDIR) type. In the UDC type, the sensor module SM, such as a camera or the like, may be disposed under a region of the display panel PNL, allowing operation of the sensor module SM, such as image capture, through the screen without requiring a physical opening in the screen. In the UDIR type, the sensor module SM may include an infrared emitter and/or detector similarly positioned beneath the display panel PNL, enabling various functions, such as facial recognition, fingerprint recognition, or gesture sensing, while maintaining an uninterrupted display surface.

In a conventional display device, after a notch is formed in an upper portion of the display area AA, an optical sensor such as a camera and an infrared (IR) sensor may be disposed in the notch. Since the notch is generally formed by removing the upper portion of the display area AA, the display area AA may be reduced and an appearance of the display device may be deteriorated.

In other conventional display devices, after a hole is formed in the display area AA, an optical sensor is generally disposed in the hole. Since the hole does not emit light, an image may be cut at the hole, thereby deteriorating the image quality.

In the display device 100 according to an embodiment of the invention, since the sensor module SM may be disposed under the display panel PNL, reduction of the display area AA and cut of the image may be prevented.

The circuit board CB may be disposed under the rear surface of the display panel PNL. The circuit board CB may include a printed circuit board (PCB) or a flexible printed circuit board (FPCB).

The cover window CW may be disposed on a front surface of the display panel PNL. The cover window CW may cover a front surface of the display panel PNL to protect the display panel PNL from an external impact.

The cover window CW may include one of a transparent plastic, a glass, and a tempered glass, but it is not limited thereto. For example, the cover window CW may have a multiple layer of sapphire glass and a gorilla glass. Further, the cover window CW may include one of polyethyleneterephthalate (PET), polycarbonate (PC), polyethersulfone (PES), polyethylene naphthalate (PEN), and polynorbornene (PNB). In addition, the cover window CW may include a tempered glass to provide improved scratch resistance and transparency.

The frame FRA may accommodate the display panel PNL and support the cover window CW. The frame FRA may further accommodate the sensor module SM and the circuit board CB. The frame FRA may secure the display panel PNL, the sensor module SM, and the circuit board CB to the display device 100 and protect the display panel PNL, the sensor module SM, and the circuit board CB from an external impact.

The display panel PNL may include a sensor area SA. The sensor area SA may be aligned with the sensor module SM to intactly transmit a stimulus, such as light incident from an exterior to the sensor module SM. Specifically, in the display device 100 according to an embodiment of the invention, since a plurality of sensor subpixels DSP1, DSP2, and DSP3 which will be described below may be disposed in the sensor area SA, the sensor area SA may transmit the external light to the sensor module SM and display an image at the same time.

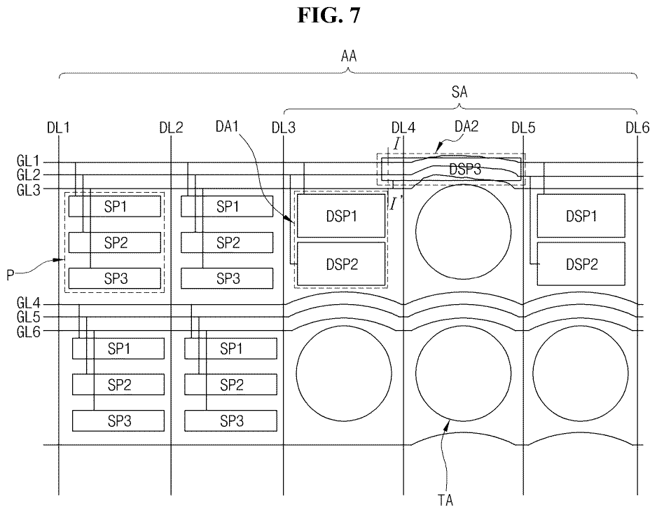

FIG. 6 is a magnified view of portion A of FIG. 5 according to a first embodiment of the invention.

Referring to FIG. 6, the display area AA may include a plurality of pixels P, and each pixel P may include the plurality of subpixels SP1, SP2, and SP3. For example, the first, second, and third subpixels SP1, SP2, and SP3 may correspond to red, green, and blue subpixels, respectively, without being limited thereto.

The sensor area SA may include a sensor display area DA and a sensor transparent area TA. The sensor display area DA may correspond to a region where an image is displayed, and the sensor transparent area TA may correspond to a transparent region where a stimulus such as an external light is transmitted to the sensor module SM. A plurality of sensor subpixels DSP1, DSP2, and DSP3 may be disposed in the sensor display area DA. For example, the first, second, and third sensor subpixels DSP1, DSP2, and DSP3 may correspond to red, green, and blue subpixels, respectively, without being limited thereto.

In FIG. 6, although the sensor area SA is exemplarily illustrated as including one sensor display area DA and three sensor transparent areas TA, the inventive concepts are not limited thereto. In another embodiment, the sensor area SA may include two or three sensor display areas DA and one or two sensor transparent areas TA.

The plurality of subpixels SP1, SP2, and SP3 of the display area AA and the plurality of sensor subpixels DSP1, DSP2, and DSP3 of the sensor display area DA may be formed to have various shapes. For example, the plurality of subpixels SP1, SP2, and SP3 and the plurality of sensor subpixels DSP1, DSP2, and DSP3 may have substantially a triangular shape or substantially a lozenge shape (diamond shape), without being limited thereto.

In the display device 100 of an UDC type or an UDIR type according to an embodiment, since the sensor area SA may include the sensor display area DA and the sensor transparent area TA, an image may be displayed and an external light may be detected in the sensor area SA. In this manner, reduction of the display area AA and cut of the image may be prevented in the display device 100 of an UDC type or an UDIR type, as compared with a conventional display device where a sensor is disposed in a notch or a hole is formed in the display area.

As discussed above, in the display device 100 of an UDC type or an UDIR type according to the first embodiment of the invention, the image may be displayed in the sensor area SA to prevent cut of the image. To prevent cut of the image, a luminance of the display area AA and a luminance of the sensor area SA should be substantially the same as each other so that a user cannot recognize the difference of luminance. However, since the sensor area SA in the display device 100 of an UDC type or an UDIR type includes the sensor display area DA (for displaying an image) and the sensor transparent area TA (for detecting light), in order to set the luminance of the sensor area SA to be the same as the luminance of the display area AA, the luminance of the sensor display area DA should be determined to be greater than the luminance of the pixel P of the display area AA.

For example, when the sensor area SA includes one sensor display area DA and three sensor transparent areas TA, the luminance of the sensor display area DA may be determined as three times of the luminance of the pixel P in the display area AA. As another example, when the sensor area SA includes three sensor display areas DA and one sensor transparent area TA, the luminance of the sensor display area DA should be determined as about 1.3 times the luminance of the pixel P in the display area AA. As still another example, when the sensor area SA includes two sensor display areas DA and one sensor transparent area TA, it may be difficult to detect light through the sensor area SA. As such, according to the first embodiment, the sensor area SA may include one sensor display area DA and three sensor transparent areas TA. However, in other embodiments, the ratio between the sensor display areas DA and sensor transparent area TA in the sensor area SA may be variously modified as needed.

To increase the luminance of the sensor display area DA of the sensor area SA greater than the luminance of the pixel P of the display area AA, a current supplied to the sensor display area DA of the sensor area SA may be increased (e.g., three times of a current of the pixel P). In this case, a lifetime of an emitting element (e.g., light emitting diode) of the sensor area SA may be shortened due to increase of the current.

In the display device according to a second embodiment of the invention, the luminance of the sensor area SA may be increased without reduction of a transmittance of the sensor transparent area TA by maximizing the sensor display area DA.

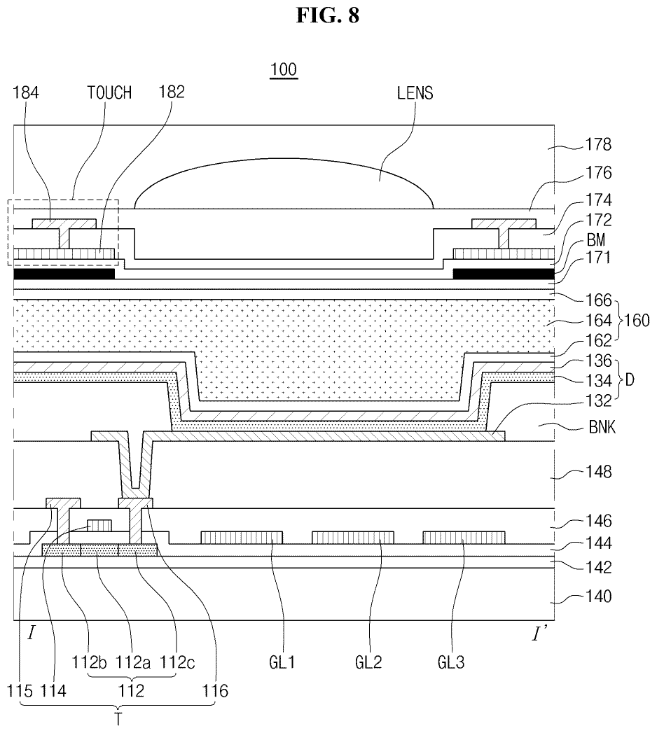

FIG. 7 is a plan view illustrating a display area and a sensor area of a display device according to a second embodiment of the invention. Hereinafter, repeated descriptions of substantially the same elements described above will be omitted.

Referring to FIGS. 5 and 7, a display device according to the second embodiment of the invention may include a display area AA displaying an image and a non-display area surrounding the display area AA.

The display area AA may include a sensing area SA corresponding to a sensor module SM. The display area AA except for the sensing area SA may include a plurality of pixels P, and the sensor area SA may include a plurality of first sensor display areas DA1, a plurality of second sensor display areas DA2, and a plurality of sensor transparent areas TA. The plurality of pixels P, the plurality of first sensor display areas DA1, the plurality of second sensor display areas DA2, and the plurality of sensor transparent areas TA may be defined by a plurality of gate lines GL1 to GL6 and a plurality of data lines DL1 to DL6.

In the display area AA, the plurality of gate lines GL1 to GL6 may be disposed along a horizontal direction, and the plurality of data lines DL1 to DL6 crossing the plurality of gate lines GL1 to GL6 may be disposed along a vertical direction.

For example, the plurality of gate lines GL1 to GL6 may include first, second, and third gate lines GL1, GL2, and GL3 adjacently disposed without intervening of the pixel P, the first sensor display area DA1, or the sensor transparent area TA, and fourth, fifth, and sixth gate lines GL4, GL5, and GL6 adjacently disposed without intervening of the pixel P, the first sensor display area DA1, or the sensor transparent area TA. The pixel P, the first sensor display area DA1, or the sensor transparent area TA may be disposed between the third gate line GL3 and the fourth gate line GL4.

The plurality of data lines DL1 to DL6 may include first to sixth data lines DL1 to DL6, and the pixel P, the first sensor display area DA1, or the sensor transparent area TA may be disposed between two adjacent ones of the first to sixth data lines DL1 to DL6.

Each pixel P of the display area AA may include a plurality of subpixels SP1, SP2, and SP3. For example, the plurality of subpixels SP1, SP2, and SP3 may include first, second, and third subpixels SP1, SP2, and SP3 corresponding to red, green, and blue colors, respectively. In some embodiments, the first, second, and third subpixels SP1, SP2, and SP3 may correspond to other colors, such as white, cyan, magenta, and yellow.

The first and second sensor display areas DA1 and DA2 of the sensor area SA may be a region where an image is displayed, and the sensor transparent area TA may be a region where light is transmitted to the sensor module SM.

For example, the first sensor display area DA1 may be disposed at a left portion or a right portion of the sensor transparent area TA, and the second sensor display area DA2 may be disposed at an upper portion or a lower portion of the sensor transparent area TA to overlap some of the gate lines GL1 to GL6.

The first and second sensor display areas DA1 and DA2 may include one or more of the sensor subpixels DSP1, DSP2, and DSP3.

For example, the first and second sensor subpixels DSP1 and DSP2 corresponding to red and green colors, respectively, may be disposed in the first sensor display area DA1, and a third sensor subpixel DSP3 corresponding to a blue color may be disposed in the second sensor display area DA2. The first and second sensor subpixels DSP1 and DSP2 may be disposed at a lower portion of the first, second, and third gate lines GL1, GL2, and GL3, and the third sensor subpixel DSP3 may overlap the first, second, and third gate lines GL1, GL2, and GL3.

The plurality of subpixels SP1, SP2, and SP3 and the plurality of sensor subpixels DSP1, DSP2, and DSP3 of FIG. 7 may define an aperture ratio as a ratio of an emission area corresponding to an area where light is emitted in each of the subpixel and the sensor subpixel.

Although not shown, a transistor (e.g., thin film transistor) and an emitting element (e.g., light emitting diode) electrically connected to each other may be disposed in each of the plurality of subpixels SP1, SP2, and SP3 and the plurality of sensor subpixels DSP1, DSP2, and DSP3. The transistor may be connected to the gate line GL1 to GL6 and the data line DL1 to DL6, and may be turned on by the gate signal from the gate line GL1 to GL6 to supply the data signal of the data line DL1 to DL6 to the emitting element.

In FIG. 7, connection of the plurality of subpixels SP1, SP2, and SP3 and the plurality of sensor subpixels DSP1, DSP2, and DSP3 to the plurality of data lines DL1 to DL6 is not shown, and only the connection of the plurality of subpixels SP1, SP2, and SP3 and the plurality of sensor subpixels DSP1, DSP2, and DSP3 to the plurality of gate lines GL1 to GL6 is shown for convenience of description.

For example, the first, second, and third gate lines GL1, GL2, and GL3 may be connected to the first, second, and third subpixels SP1, SP2, and SP3 of the pixel P in the top row, respectively, and may further be connected to the first, second, and third sensor subpixels DSP1, DSP2, and DSP3 in the top row, respectively, of the first and second sensor display areas DA1 and DA2. The first, second, and third gate lines GL1, GL2, and GL3 may be adjacently disposed at an upper portion (or lower portion) of the pixel P, the first sensor display area DA1, and the sensor transparent area TA, and the first, second, and third subpixels SP1, SP2, and SP3 of the pixel P. The first and second sensor subpixels DSP1 and DSP2 of the first sensor display area DA1 may be disposed at a lower portion (or upper portion) of the first, second, and third gate lines GL1, GL2, and GL3. Electric connection of the first, second, and third gate lines GL1, GL2, and GL3 with the first, second, and third subpixels SP1, SP2, and SP3, and electric connection of the first, second, and third gate lines GL1, GL2, and GL3 with the first, second, and third sensor subpixels DSP1, DSP2, and DSP3 may be established through a contact hole in an insulating layer, while not being limited thereto.

For example, the first and second sensor subpixels DSP1 and DSP2 may be disposed in the first sensor display area DA1 at the lower portion of the first, second, and third gate lines GL1, GL2, and GL3, and the third sensor subpixel DSP3 may be disposed in the second sensor display area DA2 overlapping the first, second, and third gate lines GL1, GL2, and GL3.

The first, second, and third gate lines GL1, GL2, and GL3 may be disposed at the upper portion of the first sensor display area DA1 and the sensor transparent area TA. When the first, second, and third gate lines GL1, GL2, and GL3 are formed of an opaque metallic material, a region corresponding to the first, second, and third gate lines GL1, GL2, and GL3 may be an opaque region where light is not transmitted. As such, since the third sensor subpixel DSP3 is disposed in the second sensor display area DA2 overlapping the first, second, and third gate lines GL1, GL2, and GL3, the sensor transparent area TA may not be reduced, and an amount of light incident to the sensor module SM through the sensor transparent area TA may not be reduced.

The areas of the pixel P of the display area AA and the first sensor display area DA1 of the sensor area SA may be substantially the same as each other. Three of the first, second, and third subpixels SP1, SP2, and SP3 may be disposed in the pixel P, and two of the first and second sensor subpixels DSP1 and DSP2 may be disposed in the first sensor display area DA1. As such, an area of each of the first and second sensor subpixels DSP1 and DSP2 may be greater than an area of each of the first, second, and third subpixels SP1, SP2, and SP3. Accordingly, an amount of light emitted from the first and second sensor subpixels DSP1 and DSP2 may be increased, and a luminance of the first and second sensor subpixels DSP1 and DSP2 may be increased without an increase of a current.

For example, a length along a vertical direction of each of the first and second sensor subpixels DSP1 and DSP2 of the first sensor display area DA1 may be greater than a length along a vertical direction of each of the first, second, and third subpixels SP1, SP2, and SP3 of the pixel P, such that an area of each of the first and second sensor subpixels DSP1 and DSP2 of the first sensor display area DA1 may be greater than an area of each of the first, second, and third subpixels SP1, SP2, and SP3 of the pixel P.

The third sensor subpixel DSP3 may be disposed in the second sensor display area DA2 overlapping the first, second, and third gate lines GL1, GL2, and GL3. The third sensor subpixel DSP3 may be disposed between the sensor transparent areas TA and extend along the first, second, and third gate lines GL1, GL2, and GL3. As shown in FIG. 7, the third sensor subpixel DSP3 may also overlap the fourth and fifth data lines DL4 and DL5.

For example, a length along a horizontal direction of the third sensor subpixel DSP3 of the second sensor display area DA2 may be greater than a length along a horizontal direction of each of the first, second, and third subpixels SP1, SP2, and SP3 of the pixel P, such that an area of the third sensor subpixel DSP3 of the second sensor display area DA2 may be greater than an area of each of the first, second, and third subpixels SP1, SP2, and SP3 of the pixel P. In addition, as shown in FIG. 7, the third sensor subpixel DSP3 in the second sensor display area DA2 overlapping the gate line GL may extend from a portion corresponding to the first sensor display area DA1 to the sensor transparent area TA. As such, a portion of the third sensor subpixel DSP3 in the second sensor display area DA2 may overlap the first sensor subpixel DSP1 in the first sensor display area DA1 along a line parallel to the data line DL4. In addition, the third sensor subpixels DSP3 overlapping different gate lines may have a different width. For example, the lowermost third sensor subpixel DSP3 shown in FIG. 7 may span over two adjacent sensor transparent areas TA in a plan view.

In FIG. 7, although the plurality of subpixels SP1, SP2, and SP3 of the pixel P and the plurality of sensor subpixels DSP1, DSP2, and DSP3 of the first and second sensor display areas DA1 and DA2 are exemplarily illustrated as having a bar shape or a rectangular shape extending along a horizontal direction parallel to the plurality of gate lines GL1, GL2, and GL3, the inventive concepts are not limited thereto. For example, the plurality of subpixels SP1, SP2, and SP3 of the pixel P and the plurality of sensor subpixels DSP1 and DSP2 of the first sensor display area DA1 may have substantially a triangular shape or substantially a lozenge shape, and the third sensor subpixel DSP3 of the second sensor display area DA2 may have substantially a bar shape or substantially a rectangular shape extending along a horizontal direction, in another embodiment.

In some embodiments, the third sensor subpixel DSP3 may have substantially a triangular shape or substantially a lozenge shape, and a portion of the third sensor subpixel DSP3 (three vertices of the triangular shape or two vertices of the lozenge shape) may protrude toward the sensor transparent area TA outside the second sensor display area DA2.

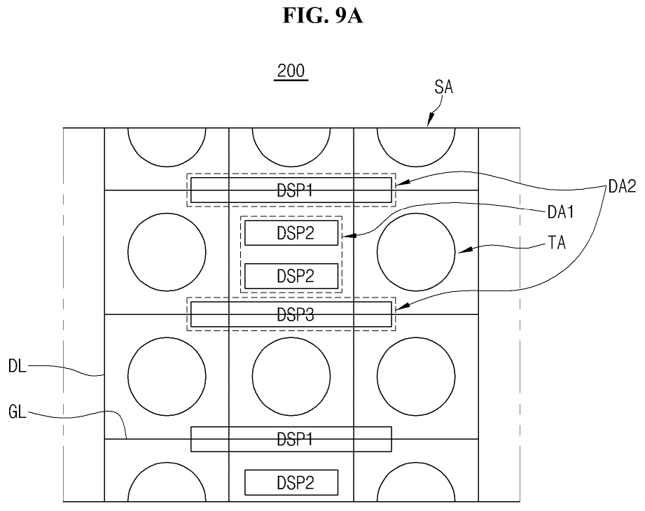

FIG. 8 is a cross-sectional view taken along line I-I′ of FIG. 7 according to an embodiment. FIG. 8 schematically illustrates the third sensor subpixel DSP3 of the display device 100 according to the second embodiment. The first, second, and third subpixels SP1, SP2, and SP3 and the first and second sensor subpixels DSP1 and DSP2 may have substantially the same structure as the third sensor subpixel DSP3 except for overlapping the first, second, and third gate lines GL1, GL2, and GL3, and thus, repeated descriptions thereof will be omitted.

Referring to FIG. 8, a first buffer layer 142 may be disposed on a substrate 140. The substrate 140 may include a hard material such as a glass or a soft material such as a plastic material.

When the substrate 140 includes a plastic material, the substrate 140 may include at least one of polyimide (PI), polymethylmethacrylate (PMMA), polyethylene terephthalate (PET), polyether sulfone (PES), and polycarbonate (PC), without being limited thereto.

For example, when the substrate 140 includes polyimide, the substrate 140 may include a plurality of polyimide layers. Further, an inorganic layer may be disposed between the polyimide layers, without being limited thereto.

The first buffer layer 142 may be disposed on substantially the entire substrate 140 to increase an adhesive strength between layers and the substrate 140, and to block an alkali ingredient released from the substrate 140. Further, the first buffer layer 142 may delay diffusion of a moisture or an oxygen permeating the substrate 140.

The first buffer layer 142 may have a single layer or a multiple layer of an inorganic insulating material such as silicon nitride (SiNx) and silicon oxide (SiOx). When the first buffer layer 142 has a multiple layer, a layer of silicon nitride (SiNx) and a layer of silicon oxide (SiOx) may be alternated with each other. In some embodiments, the first buffer layer 142 may be omitted based on a type and a material of the substrate 140 and a structure and a type of the thin film transistor.

A thin film transistor T may be disposed on the first buffer layer 142. Although a driving thin film transistor among a plurality of thin film transistors is exemplarily shown in FIG. 8, other thin film transistors such as a switching thin film transistor may be disposed on the substrate 140. Further, although the thin film transistor T is exemplarily illustrated as having a top gate structure in FIG. 8, in some embodiments, the thin film transistor T may have other structures such as a bottom gate structure.

The thin film transistor T may include a semiconductor layer 112 on the first buffer layer 142, a gate insulating layer 144 on the semiconductor layer 112, a gate electrode 114 on the gate insulating layer 144, a first interlayer insulating layer 146 on the gate electrode 114, and source and drain electrodes 115 and 116 on the first interlayer insulating layer 146.

The semiconductor layer 112 may include a polycrystalline semiconductor material. For example, the polycrystalline semiconductor material may include low temperature polycrystalline silicon (LTPS) having a relatively high mobility, without being limited thereto.

The semiconductor layer 112 may include an oxide semiconductor material. For example, the oxide semiconductor material may include one of indium gallium zinc oxide (IGZO), indium zinc oxide (IZO), indium gallium tin oxide (IGTO), and indium gallium oxide (IGO), without being limited thereto. The semiconductor layer 112 has a channel region 112a of an intrinsic material at a central portion thereof, and source and drain regions 112b and 112c including a doped material at both sides of the channel region 112a.

The gate insulating layer 144 may have a single layer or a multiple layer of an inorganic insulating material such as silicon nitride (SiNx) and silicon oxide (SiOx), without being limited thereto.

The gate electrode 114 may include a metallic material. For example, the gate electrode 114 may have a single layer or a multiple layer of one of molybdenum (Mo), aluminum (Al), chromium (Cr), gold (Au), titanium (Ti), nickel (Ni), neodymium (Nd), copper (Cu), and an alloy thereof, without being limited thereto.

The first interlayer insulating layer 146 may have a single layer or a multiple layer of an organic insulating material such as photoacryl or an inorganic insulating material such as silicon nitride (SiNx) and silicon oxide (SiOx). Further, the first interlayer insulating layer 146 may have a multiple layer of an organic layer and an inorganic layer, without being limited thereto.

The source and drain electrodes 115 and 116 may have a single layer or a multiple layer of one of molybdenum (Mo), aluminum (Al), chromium (Cr), gold (Au), titanium (Ti), nickel (Ni), neodymium (Nd), copper (Cu), and an alloy thereof, without being limited thereto. The source and drain electrodes 115 and 116 may be connected to the source and drain regions 112b and 112c, respectively, of the semiconductor layer 112 through contact holes in the gate insulating layer 144 and the first interlayer insulating layer 146.

The semiconductor layer 112, the gate electrode 114, the source electrode 115, and the drain electrode 116 constitute a thin film transistor T.

Although not shown, a bottom shielding metal layer may be disposed on the substrate 140 under the semiconductor layer 112. The bottom shielding metal layer may minimize a back channel phenomenon generated due to charges trapped in the substrate 140 to prevent a residual image or deterioration of a transistor. The bottom shielding metal layer may have a single layer or a multiple layer of one of titanium (Ti), molybdenum (Mo), and an alloy thereof, without being limited thereto.

The first, second, and third gate lines GL1, GL2, and GL3 may be disposed on the gate insulating layer 144. The first, second, and third gate lines GL1, GL2, and GL3 may be formed of the same metallic material as the gate electrode 114 or may be formed of a metallic material different from the gate electrode 114.

In some embodiments, the first, second, and third gate lines GL1, GL2, and GL3 may be formed on a layer different from a layer on which the gate electrode 114 is disposed. For example, the first, second, and third gate lines GL1, GL2, and GL3 may be disposed on the first buffer layer 142 or may be disposed on the first interlayer insulating layer 146.

Although the first, second, and third gate lines GL1, GL2, and GL3 and the gate electrode 114 are exemplarily illustrated as being spaced apart from each other in FIG. 8, the inventive concepts are not limited thereto. For example, the first, second, and third gate lines GL1, GL2, and GL3 and the gate electrode 114 may be formed as a monolithic body in another embodiment.

A planarizing layer 148 may be disposed on the thin film transistor T over the substrate 140. The planarizing layer 148 may include an organic insulating material such as photoacryl, without being limited thereto. The planarizing layer 148 may have a multiple layer of an inorganic layer and an organic layer.

A light emitting diode D may be disposed on the planarizing layer 148. The light emitting diode D may include a first electrode 132, an emitting layer 134, and a second electrode 136.

The first electrode 132 may be disposed on the planarizing layer 148 and may be electrically connected to the drain electrode 116 of the thin film transistor T through a contact hole in the planarizing layer 148. The first electrode 132 may include at least one of silver (Ag), aluminum (Al), gold (Au), molybdenum (Mo), tungsten (W), chromium (Cr), and an alloy thereof. Alternatively, the first electrode 132 may include a transparent conductive material such as indium tin oxide (ITO) and indium zinc oxide (IZO).

When the display device 100 has a top emission type, the first electrode 132 may further include an opaque conductive material for using the first electrode 132 as a reflective layer. When the display device 100 has a bottom emission type, the first electrode 132 may include a transparent conductive material such as indium tin oxide (ITO) and indium zinc oxide (IZO).

A bank layer BNK may be disposed in a boundary region of each subpixel on the planarizing layer 148. The bank layer BNK may function as a wall defining the subpixel. The bank layer BNK may prevent a mixture of lights of various colors emitted from adjacent subpixels.

The bank layer BNK may include at least one of an inorganic insulating material such as silicon nitride (SiNx) and silicon oxide (SiOx), an organic insulating material such as benzocyclobutene (BCB), acrylic resin, epoxy resin, phenolic resin, polyamide resin and polyimide resin, and a photosensitive material including a black pigment, without being limited thereto.

The emitting layer 134 may be disposed on a top surface of the first electrode 132, a side surface of the bank layer BNK, and a top surface of the bank layer BNK in the display area AA to extend toward the non-display area NA.

The emitting layer 134 may include a red emitting layer emitting a red colored light in a red subpixel SP, a green emitting layer emitting a green colored light in a green subpixel SP, and a blue emitting layer emitting a blue colored light in a blue subpixel SP. For example, the emitting layer 134 may include an organic emitting layer, an inorganic emitting layer, a nano-sized material layer, a quantum dot layer, an emitting layer of a micro light emitting diode (LED), and an emitting layer of a mini LED, without being limited thereto.

The emitting layer 134 may include an emitting material layer, an electron injecting layer injecting an electron, a hole injecting layer injecting a hole, an electron transporting layer transporting an electron, a hole blocking layer blocking a hole, an electron blocking layer blocking an electron, and a hole transporting layer transporting a hole, without being limited thereto.

The second electrode 136 may be disposed on the emitting layer 134. The second electrode 136 may have a single layer or a multiple layer of a metallic material or an alloy of metallic materials. Alternatively, the second electrode 136 may include a transparent conductive material such as indium tin oxide (ITO) and indium zinc oxide (IZO), without being limited thereto.

When the display device 100 has a top emission type, the second electrode 136 may include a half transmissive conductive material transmitting light. For example, the second electrode 136 may include at least one of alloys of LiF/Al, CsF/Al, Mg:Ag, Ca/Ag, Ca:Ag, LiF/Mg:Ag, LiF/Ca/Ag, and LiF/Ca:Ag.

When the display device 100 has a bottom emission type, the second electrode 136 may include an opaque conductive material for using the second electrode 136 as a reflective layer. For example, the second electrode 136 may include at least one of silver (Ag), aluminum (Al), gold (Au), molybdenum (Mo), tungsten (W), chromium (Cr), and an alloy thereof.

The light emitting diode D may have a tandem structure. The tandem structure may include a plurality of emitting layers and a charge generating layer between the plurality of emitting layers. The charge generating layer for adjusting a charge balance of the plurality of organic layers may have a multiple layer including first and second charge generating layers. The charge generating layer may include a negative (N) type charge generating layer and a positive (P) type charge generating layer. For example, the charge generating layer may include an emitting layer doped with an alkali metal such as lithium (Li), sodium (Na), potassium (K), and cesium (Cs) or an alkali earth metal such as magnesium (Mg), strontium (Sr), barium (Ba), and radium (Ra), without being limited thereto.

An encapsulating layer 160 may be disposed on the light emitting diode D in the display area AA and the non-display area NA to encapsulate the light emitting diode D. When the light emitting diode D is exposed to a moisture or an oxygen, a pixel shrinkage phenomenon where an emission area is reduced or deterioration of a dark spot in the emission area may occur. Further, a moisture or an oxygen may oxidize the electrode of a metallic material. The encapsulating layer 160 may block permeation of a moisture or an oxygen from an exterior to prevent deterioration of the light emitting diode D and the electrodes.

Although the encapsulating layer 160 is exemplarily illustrated as having a triple layer of first, second, and third encapsulating layers 162, 164, and 166 in FIG. 8, the encapsulating layer 160 may have a double layer or a quadruple layer in another embodiment.

The first and third encapsulating layer 162 and 166 may have a single layer or a multiple layer of an inorganic material such as silicon oxide (SiOx), silicon oxynitride (SiON), and silicon nitride (SiNx). The first and third encapsulating layer 162 and 166 may further include an organic material between the inorganic materials, without being limited thereto. The second encapsulating layer 164 may include epoxy resin, for example.

A second buffer layer 171 may be disposed on the encapsulating layer 160, and a black matrix BM may be disposed on the second buffer layer 171. The second buffer layer 171 may have a single layer or a multiple layer of an inorganic insulating material such as silicon nitride (SiNx) and silicon oxide (SiOx). The black matrix BM may absorb light. The black matrix BM may block or absorb light emitted or transmitted from the adjacent sensor display area DA1 and DA2 and the sensor transparent area TA to prevent a mixture of colored lights. The black matrix BM may include a black resin or a metallic material such as chromium (Cr) and chromium oxide (CrOx), without being limited thereto.

A second interlayer insulating layer 172 may be disposed on the black matrix BM and the second buffer layer 171, and a touch sensing unit TOUCH may be disposed on the second interlayer insulating layer 172. The touch sensing unit TOUCH may be disposed in the display area AA to sense a touch input. The touch sensing unit TOUCH may sense an external touch information caused by a finger of a user or a touch pen.

The second interlayer insulating layer 172 may block a permeation of a solution such as a developing solution and an etching solution for forming the touch sensing unit TOUCH into the organic light emitting diode D, and block a permeation of an external moisture or an external oxygen into the light emitting diode D. Further, the second interlayer insulating layer 172 may prevent an opening of a plurality of touch electrodes 184 due to an external impact and block an interference signal generated from driving of the touch sensing unit TOUCH.

The second interlayer insulating layer 172 may have a single layer or a multiple layer of an organic insulating material such as photoacryl or an inorganic insulating material such as silicon nitride (SiNx) and silicon oxide (SiOx). Further, the second interlayer insulating layer 172 may have a multiple layer of an organic layer and an inorganic layer, without being limited thereto.

The touch sensing unit TOUCH may include a plurality of touch connecting electrodes 182 on the second interlayer insulating layer 172, a first protecting layer 174 on the plurality of touch connecting electrodes 182, a plurality of touch electrodes 184 on the first protecting layer 174, and a second protecting layer 176 on the plurality of touch electrodes 184.

The plurality of touch electrodes 184 may be connected to the plurality of touch connecting electrodes 182 through contact holes in the second interlayer insulating layer 172. Although not shown, each of the plurality of touch connecting electrodes 182 may electrically connect adjacent touch electrodes 184.

The plurality of touch connecting electrodes 182 and the plurality of touch electrodes 184 may include a transparent conductive material such as indium tin oxide (ITO) and indium zinc oxide (IZO), or may have a single layer or a multiple layer of one of molybdenum (Mo), aluminum (Al), chromium (Cr), gold (Au), titanium (Ti), nickel (Ni), neodymium (Nd), copper (Cu), and an alloy thereof, without being limited thereto.

The second protecting layer 176 may include an organic material such as photoacryl or may have a multiple layer of an organic layer and an inorganic layer.

A lens LENS may be disposed on the second protecting layer 176. When the display device 100 has a bottom emission type, the lens LENS may be disposed under the light emitting diode D or under the substrate 140. The lens LENS may be disposed to correspond to an opening of the black matrix BM where light is emitted.

The lens LENS may have an upwardly convex shape. When the display device 100 has a bottom emission type, the lens LENS may have a downwardly convex shape.

The lens LENS in each of the first, second, and third subpixels SP1, SP2, and SP3 and the first, second, and third sensor subpixels DSP1, DSP2, and DSP3 may focus light emitted from the light emitting diode D to improve a luminance of the display device 100.

The lens LENS may include a polymer resin having an excellent light transmittance. For example, the lens LENS may include one of acrylic resin, polyimide (PI), polyamide (PA), polycarbonate (PC), polystyrene (PS), and polyethylene terephthalate (PET), without being limited thereto.

A third protecting layer 178 may be disposed on the lens LENS. The third protecting layer 178 may have a single layer of an organic material or an inorganic material, or may have a multiple layer of an inorganic layer and an organic layer.

Although the display device 100 is exemplarily illustrated as including the lens LENS for improving a luminance in FIG. 8, the inventive concepts are not limited thereto. For example, the display device may not include the lens LENS for improving a luminance in another embodiment. In some embodiments, the lens may not be disposed in the first, second, and third subpixels SP1, SP2, and SP3 and the first and second sensor subpixels DSP1 and DSP2 and may be disposed in the third sensor subpixel DSP3.

In the display device 100 according to the second embodiment of the invention, since the third sensor subpixel DSP3 may be disposed in the second sensor display area DA2 overlapping the first, second, and third gate lines GL1, GL2, and GL3, the emission area of the sensor area SA is increased. As such, even when the amount of a current applied to the first, second, and third sensor subpixels DSP1, DSP2, and DSP3 were to be reduced, a difference of luminance between the display area AA and the sensor area SA may be minimized, thereby preventing or at least suppressing shortening of a lifetime of the display device 100.

The first, second and third sensor subpixels DSP1, DSP2 and DSP3 according to embodiments of the invention may have various configurations.

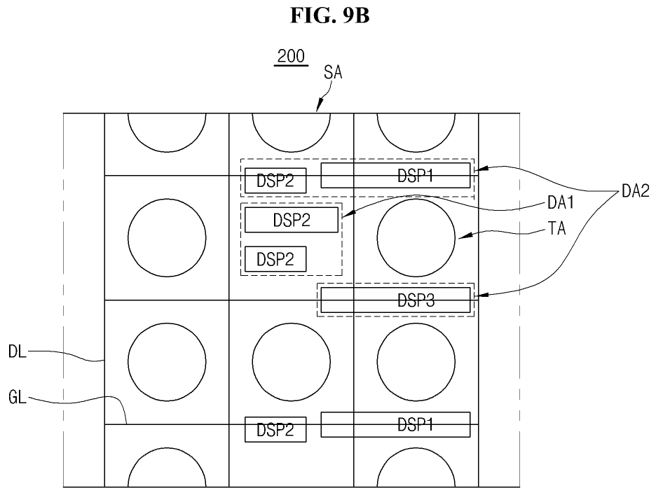

FIGS. 9A and 9B are views schematically illustrating a sensing area of a display device according to third and fourth embodiments, respectively, of the invention. Since an arrangement structure of first, second, and third subpixels SP1, SP2, and SP3 of a display area AA of the display device 200 according to third and fourth embodiments may be substantially the same as those described in the second embodiment, FIGS. 9A and 9B mainly show an arrangement structure of first, second, and third sensor subpixels DSP1, DSP2, and DSP3 of a sensor area SA.

Referring to FIG. 9A, a sensor area SA of a display device 200 according to the third embodiment of the invention may include first and second sensor display areas DA1 and DA2 and a sensor transparent area TA. Two second sensor subpixels DSP2 may be disposed in the first sensor display area DA1, a first sensor subpixel DSP1 may be disposed in a second sensor display area DA2 overlapping a gate line GL at an upper portion of the first sensor display area DA1, and a third sensor subpixel DSP3 may be disposed in the second sensor display area DA2 overlapping the gate line GL at a lower portion of the first sensor display area DA1. The plurality of sensor subpixels DSP2 of a first color may be disposed in the first sensor display area DA1, and the sensor subpixels DSP1 and DSP3 of second and third colors may be disposed in the second sensor display areas DA2 at the upper and lower portion of the first sensor display area DA1.

The two second sensor subpixels DSP2 may be disposed in the first sensor display area DA1 at the upper portion or the lower portion of the gate line GL, and the first and third sensor subpixels DSP1 and DSP3 in the second sensor display area DA2 overlapping the gate line GL may extend from a portion corresponding to the first sensor display area DA1 to the sensor transparent area TA. As such, areas of the first, second, and third sensor subpixels DSP1, DSP2, and DSP3 may be maximized, and an amount of light emitted from the first, second, and third sensor subpixels DSP1, DSP2, and DSP3 may increase. Further, the lifetime of the display device 200 may be improved by minimizing an amount of a current supplied to the first, second, and third sensor subpixels DSP1, DSP2, and DSP3. More particularly, since the areas of the first, second, and third sensor subpixels DSP1, DSP2, and DSP3 may be maximized, it is possible to prevent an excessive amount of current from flowing into the sensor subpixels of the sensor display area DA of the sensor area SA to achieve substantially the same luminance between the sensor display area DA of the sensor area SA and the pixel P of the display area AA, while retaining high transmittance of the sensor transparent area TA.

For example, a length along a horizontal direction of the second sensor subpixel DSP2 of the first sensor display area DA1 may be the same as a length along the horizontal direction of each of first, second, and third subpixels SP1, SP2, and SP3 of a pixel P, whereas a length along the horizontal direction of each of the first and third sensor subpixels DSP1 and DSP3 of the second sensor display area DA2 may be greater than a length along the horizontal direction of each of the first, second, and third subpixels SP1, SP2, and SP3 in the pixel P. As such, a total area of each of the first, second, and third sensor subpixels DSP1, DSP2, and DSP3 may be greater than an area of each of the first, second, and third subpixels SP1, SP2, and SP3.

The first, second, and third sensor subpixels DSP1, DSP2, and DSP3 may correspond to red, green, and blue colors, respectively, without being limited thereto.

Referring to FIG. 9B, a sensor area SA of a display device 200 according to the fourth embodiment of the invention may include first and second sensor display areas DA1 and DA2 and a sensor transparent area TA. Three second sensor subpixels DSP2 may be disposed in the first sensor display area DA1, first sensor subpixel DSP1 may be disposed in a second sensor display area DA2 overlapping a gate line GL at an upper portion of the first sensor display area DA1, and a third sensor subpixel DSP3 may be disposed in the second sensor display area DA2 overlapping the gate line GL at a lower portion of the first sensor display area DA1. The plurality of sensor subpixels of a first color may be disposed in the first sensor display area DA1, the sensor subpixel of a second color may be disposed in the second sensor display areas DA2 at the upper portion of the first sensor display area DA1, and the sensor subpixel of a third color may be disposed in the second sensor display areas DA2 at the lower portion of the first sensor display area DA1.

Three second sensor subpixels DSP2 may be disposed in the first sensor display area DA1 at the upper portion or the lower portion of the gate line GL, and the first and third sensor subpixels DSP1 and DSP3 in the second sensor display areas DA2 overlapping the gate line GL may extend from a portion corresponding to the first sensor display area DA1 to the sensor transparent area TA. As such, total areas of the first, second, and third sensor subpixels DSP1, DSP2, and DSP3 may be maximized, and an amount of light emitted from the first, second, and third sensor subpixels DSP1, DSP2, and DSP3 may be increased. Further, the lifetime of the display device 200 may be improved by minimizing an amount of a current supplied to the first, second, and third sensor subpixels DSP1, DSP2, and DSP3. More particularly, since the total areas of the first, second, and third sensor subpixels DSP1, DSP2, and DSP3 may be maximized, it is possible to prevent an excessive amount of current from flowing into the sensor subpixels of the sensor display area DA of the sensor area SA to achieve substantially the same luminance between the sensor display area DA of the sensor area SA and the pixel P of the display area AA, while retaining high transmittance of the sensor transparent area TA.

For example, a length along a horizontal direction of at least one of the second sensor subpixels DSP2 of the first sensor display area DA1 may be the same as a length along the horizontal direction of each of first, second, and third subpixels SP1, SP2, and SP3 of a pixel P, and a length along the horizontal direction of each of the first and third sensor subpixels DSP1 and DSP3 of the second sensor display area DA2 may be greater than a length along the horizontal direction of each of the first, second, and third subpixels SP1, SP2, and SP3 in the pixel P. As such, a total area of each of the first, second, and third sensor subpixels DSP1, DSP2, and DSP3 may be greater than an area of each of the first, second and third subpixels SP1, SP2, and SP3.

The first, second, and third sensor subpixels DSP1, DSP2, and DSP3 may correspond to red, green, and blue colors, respectively, without being limited thereto.

In the display device 200 according to third and fourth embodiments of the invention, the plurality of sensor subpixels of one color may be disposed in the first sensor display area DA1, and the plurality of sensor subpixels of other colors may be disposed in the second sensor display areas DA2 overlapping the gate line. In this manner, a total area of each of the first, second, and third sensor subpixels DSP1, DSP2, and DSP3 may be maximized.

Although the sensor subpixel of the sensor area SA is exemplarily illustrated as overlapping the gate line in FIGS. 9A and 9B, the inventive concepts are not limited thereto. For example, in some embodiments, the subpixel of the pixel P of the display area AA may be disposed to overlap the gate line.

Since the subpixel may be disposed to overlap the gate line, the aperture ratio of the display device may be improved. Specifically, since light emitted from the light emitting diode may be focused by the lens in the subpixel, the color mixture of the adjacent subpixels may be prevented even when the subpixel is disposed to overlap the gate line.

Accordingly, in the display device according to first to fourth embodiments of the invention, since the sensor area may include the sensor display area and the sensor transparent area, an image may be displayed and the external light may be detected in the sensor area. As such, reduction of the display area and cut of the image may be prevented as compared with a conventional display device having a notch or a hole for a sensor.

Further, since some of the sensor subpixels may be disposed to overlap the gate line, the emission area of the sensor area may be increased. Accordingly, since the luminance difference of the display area and the sensor area may be minimized by reducing the amount of the current applied to the sensor subpixel, shortening of the lifetime of the display device may be prevented.

In addition, since the amount of the current applied to the sensor subpixel may be reduced, the display device of a low power consumption may be obtained.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a display panel comprising a display area having a sensing area, the sensing area comprising a first sensor display area, a second sensor display area, and a sensor transparent area;
a sensor module disposed under the display panel and corresponding to the sensing area; and
a plurality of sensor subpixels disposed in the first and second sensor display areas,
wherein:
the sensor transparent area is defined by a plurality of gate lines and a plurality of data lines; and
the second sensor display area overlaps the plurality of gate lines.

2. The display device of claim 1, wherein:
the plurality of gate lines comprises first, second, and third gate lines disposed at an upper portion of the first sensor display area and the sensor transparent area; and
the plurality of sensor subpixels comprises first, second, and third sensor subpixels connected to the first, second, and third gate lines, respectively.

3. The display device of claim 2, wherein the first, second, and third sensor subpixels correspond to red, green, and blue colors, respectively.

4. The display device of claim 2, wherein:
the first and second sensor subpixels are disposed in the first sensor display area; and
the third sensor subpixel is disposed in the second sensor display area.

5. The display device of claim 4, wherein the third sensor subpixel overlaps the plurality of gate lines.

6. The display device of claim 5, wherein the third sensor subpixel extends from a portion corresponding to the first sensor display area to a portion corresponding to the sensor transparent area.

7. The display device of claim 2, wherein:
the second sensor subpixel is formed in plural and at least one of the second sensor subpixels is disposed in the first sensor display area;
the first sensor subpixel is disposed in the second sensor display area overlapping the plurality of gate lines at an upper portion of the first sensor display area; and
the third sensor subpixel is disposed in the second sensor display area overlapping the plurality of gate lines at a lower portion of the first sensor display area.

8. The display device of claim 7, wherein each of the first and third sensor subpixels overlaps the plurality of gate lines.

9. The display device of claim 2, wherein:
the second sensor subpixel is formed in plural and at least one of the second sensor subpixels is disposed in the first sensor display area;
the first sensor subpixel is disposed in the second sensor display area overlapping the plurality of gate lines at an upper portion of the first sensor display area;
the third sensor subpixel is disposed in the second sensor display area overlapping the plurality of gate lines at a lower portion of the first sensor display area; and
a width of at least one of the first sensor subpixel and the third sensor subpixel is greater than that of the second sensor subpixel.

10. The display device of claim 1, wherein each of the plurality of sensor subpixels comprises:
a substrate;
a thin film transistor disposed on the substrate; and
a light emitting diode disposed on the thin film transistor.

11. The display device of claim 10, wherein each of the plurality of sensor subpixels further comprises:
a black matrix configured to block light emitted from an adjacent one of the plurality of sensor subpixels; and
a lens corresponding to an opening of the black matrix.

12. The display device of claim 10, wherein the plurality of sensor subpixels in the first sensor display area are structured the same as the plurality of sensor subpixels in the second sensor display area.

13. The display device of claim 11, wherein each of the plurality of sensor subpixels further comprises a touch sensing unit disposed between the black matrix and the lens.

14. A display device comprising:
a substrate comprising a plurality of pixels defined by a plurality of gate lines and a plurality of data lines; and
a plurality of subpixels in each of the plurality of pixels,
wherein at least one of the plurality of subpixels overlaps at least one of the plurality of gate lines.

15. The display device of claim 14, wherein each of the plurality of subpixels comprises:
a thin film transistor disposed on the substrate;
a light emitting diode disposed on the thin film transistor;
a black matrix configured to block a light emitted from an adjacent one of the plurality of subpixels; and
a lens corresponding to an opening of the black matrix.

16. The display device of claim 14, wherein the substrate comprises a sensor area configured to display an image and transmit light to a sensor module.

17. A display device comprising:
a display panel comprising a plurality of signal lines, the display panel having an active area and a sensing area; and
a sensor module disposed on the display panel and corresponding to the sensing area,
wherein:
the active area includes a plurality of pixels, each pixel including a plurality of subpixels;
the sensing area includes a first sensor display area, a second sensor display area, and a sensor transparent area, each of the first and second sensor display areas including a sensor subpixel, and
an area of at least one of the sensor subpixels is greater than an area of at least one of the subpixels in the active area.

18. The display device of claim 17, wherein the sensor subpixel of the second sensor display area overlaps at least one of the signal lines.

19. The display device of claim 17, wherein a width of the sensor subpixel in the second sensor display area is greater than a width of at least one of the subpixels in the active area.

20. The display device of claim 19, wherein:
a width of the sensor subpixel in the second sensor display area is greater than a width of the sensor subpixel in the first sensor display area; and
the sensor subpixels in the first and second sensor display areas are configured to emit light of different colors.

21. The display device of claim 19, wherein the sensor subpixel in the first sensor display area is formed in plural, and the number of the sensor subpixels in the first sensor display area is greater than the number of the sensor subpixel in the second sensor display area.

22. The display device of claim 21, wherein the second sensor display area is formed in plural, and widths of the sensor subpixels in the second sensor display areas are different from each other.

23. The display device of claim 17, wherein the second sensor display area is formed in plural, and the sensor subpixels in adjacent second sensor display areas are configured to emit light of different colors.

24. The display device of claim 17, wherein:
at least one of the sensor subpixels comprises a lens;
the plurality of signal lines includes a plurality of gate lines and a plurality of data lines; and
at least a portion of the sensor subpixel in the second sensor display area overlaps at least one of the sensor subpixels in the first sensor display area along a line parallel to one of the data lines.

25. The display device of claim 24, wherein the sensor transparent area is formed in plural, and the sensor subpixel in the second sensor display area spans over two adjacent sensor transparent areas in a plan view.

26. The display device of claim 25, wherein:
the sensor transparent area is configured to transmit an external light to the sensor module; and
the number of the sensor transparent area is greater than the number of the first and second sensor display areas.

27. The display device of claim 25, wherein:
the number of the subpixels in one pixel is greater than the number of the sensor subpixels in the first sensor display area;
an area of the one pixel is substantially the same as an area of the first sensor display area; and
each sensor subpixel in the first sensor display area is configured to emit light having a greater luminance than that emitted from each subpixel.

28. The display device of claim 17, wherein:
the sensor subpixel in the second sensor display area overlaps two signal lines that intersect each other; and
the sensor subpixel in the first sensor display area does not overlap the signal lines.

29. The display device of claim 17, wherein the sensor module comprises at least one of a camera, an illuminance sensor, and a fingerprint sensor.
